(19) United States
(12) Patent Application Publication
(10) Pub. No.: US 2020/0106440 A1
(43) Pub. Date: Apr. 2, 2020

(54) SEMICONDUCTOR DEVICE AND METHODS OF SETTING VOLTAGES

(71) Applicant: RENESAS ELECTRONICS CORPORATION, Tokyo (JP)

(72) Inventor: Fumiki KAWAKAMI, Tokyo (JP)

(21) Appl. No.: 16/572,088

(22) Filed: Sep. 16, 2019

(30) Foreign Application Priority Data
Oct. 2, 2018 (JP) 2018-187311

(51) Int. Cl. H03K 19/003

(52) U.S. Cl. CPC H03K 19/00369; G01K 7/16

(57) ABSTRACT

The present invention provides a semiconductor device and a voltage-setting method capable of suppressing degradation of elements constituting a semiconductor device. The semiconductor device comprises a logical block, a diagnosis section for diagnosing the operation of the logical block, and a voltage controller for setting a voltage value for operating the logical block using a lower limit voltage value diagnosed by the diagnosis section when the logical block operates normally.

### CROSS-REFERENCE TO RELATED APPLICATIONS

The disclosure of Japanese Patent Application No. 2018-187311 filed on Oct. 2, 2018 including the specification, drawings and abstract is incorporated herein by reference in its entirety.

### BACKGROUND

The present invention relates to a semiconductor device and a voltage setting method, for example, a semiconductor device and a voltage setting method for setting a voltage for operating a logical block.

The aging degradation of semiconductor device caused by NBTI (Negative Bias Temperature Instability) and HCI (Hot Carrier Injection) is problematic. For this reason, various techniques related to the degradation of the elements constituting the semiconductor device have been proposed. For example, Japanese unexamined Patent Application publication No. 2017-135131 discloses an integrated circuit comprising a self-test controller for controlling a LBIST (Logic Built-In Self-Test, a temperature sensor, a clock-cycle control circuit, and a power circuit, which is capable of easily determining ageing degradation while taking into account the effects of temperature.

### SUMMARY

As the miniaturization of semiconductor processes progresses, the lifetime of the elements constituting the semiconductor device is shortened. Therefore, design considering aging deterioration during operation of a product is increasingly demanded, and the degree of design difficulty is increasing. Therefore, there is a need for a technique capable of suppressing the progress of aging deterioration. In the technique disclosed in Japanese unexamined Patent Application publication No. 2017-135131, the aging degradation of the target circuit can be determined by changing the frequency of the clock or the power supply voltage to perform the test, but the progression of the aging degradation cannot be suppressed.

Other objects and novel features will become apparent from the description of this specification and the accompanying drawings.

According to one embodiment, the voltage controller sets a voltage value for operating the logical block using a lower limit voltage value at which the logical block is diagnosed by the diagnosis section as operating normally.

According to the above-mentioned embodiment, it is possible to suppress degradation of the elements constituting the semiconductor device.

### BRIEF DESCRIPTION OF THE DRAWINGS

FIG. 1 is a block diagram showing an exemplary configuration of a Semiconductor device according to an outline of an embodiment of the present invention;

FIG. 2 is a block diagram showing an example of a configuration of an MCU according to a first embodiment;

FIG. 3 is a flow chart illustrating an example of the setting operation of the Core voltage in the MCU according to the first embodiment is shown.

FIG. 4 is a block diagram illustrating an example of a configuration of the MCU according to the second embodiment;

FIG. 5 is a graphical representation of the Temperature characteristics of Logical block.

FIG. 6 is a flow chart illustrating an example of the setting operation of the Core voltage in the MCU according to the second embodiment;

FIG. 7 is a block diagram illustrating an example of the configuration of the MCU according to the third embodiment;

FIG. 8 is a flow chart illustrating an example of the setting operation of the Core voltage in the MCU according to the third embodiment;

### DETAILED DESCRIPTION

For clarity of explanation, the following description and drawings are appropriately omitted and simplified. In the drawings, the same elements are denoted by the same reference numerals, and a repetitive description thereof is omitted as necessary.

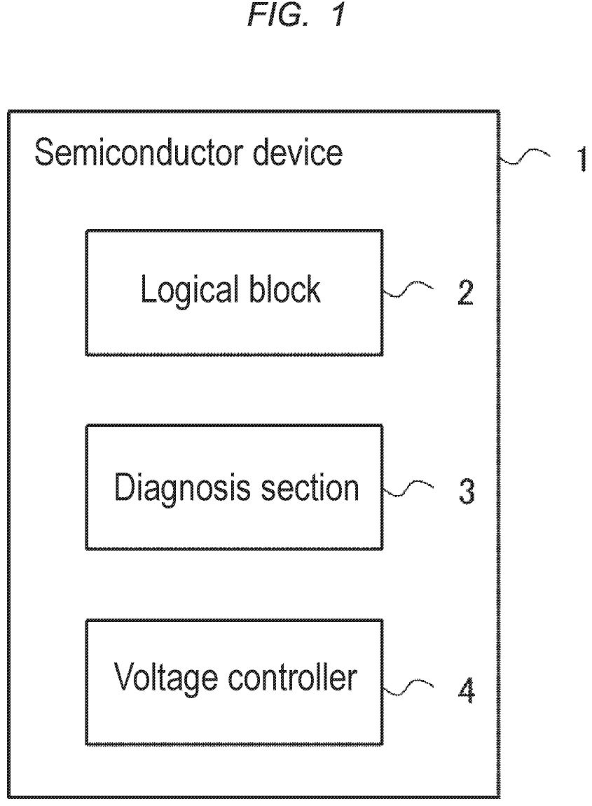

Prior to the detailed description of the embodiment, the outline of the embodiment will be described first. FIG. 1 is a block diagram showing an exemplary configuration of a semiconductor device 1 according to an outline of an embodiment of the present invention. As shown in FIG. 1, the semiconductor device 1 includes a logical block 2, a diagnosis section 3, and a voltage controller 4.

Logical block 2 is a block of circuits for performing logical operations. The diagnosis section 3 diagnoses the operation of the logical block 2. The diagnosis section 3 diagnoses, for example, whether or not the logical block 2 has reached a predetermined performance using a predetermined diagnostic mechanism. The predetermined diagnostic mechanism is, for example, LBIST, but any known diagnostic mechanism can be used without limitation. For example, the diagnosis section 3 may diagnose the logical block 2 in a dual-core lockstep manner.

The voltage controller 4 sets voltages for operating the logical block 2. In particular, the voltage controller 4 sets a voltage value for operating the logical block 2 by using a lower limit voltage value diagnosed by the diagnosis section 3 when the logical block 2 operates normally. The voltage controller 4 may use the lower limit voltage value as a voltage value for operating the logical block 2, or may use a value obtained by adding predetermined margins to the lower limit voltage value as a voltage value for operating the logical block 2. The logical block 2 operates at voltages set by the voltage controller 4. It should be noted that the voltage controller 4 performs the above-mentioned setting, for example, as the voltage value at the time of normal use of the logical block 2. Normal use refers to the use of the logical block 2 to perform a process according to user programs by the logical block 2, for example, rather than the use of the logical block 2 for a test operation, such as an operation to perform a test (e.g., LBIST) on the logical block 2.

In such a configuration, in the semiconductor device 1, first, a temporary voltage value for operating the logical block 2 is set, and whether or not the logical block 2 normally operates is diagnosed by the temporary voltage value, thereby searching for a lower limit voltage value at which the logical block 2 normally operates. Then, the main setting of the voltage value for operating the logical block 2 is performed using the found lower limit voltage value.

Generally, the higher the operating voltages, the more accelerated the degradation of the elements included in the semiconductor device. According to the semiconductor device 1, it is possible to set as low voltages as possible while ensuring the normal operation of the logical block 2. Therefore, deterioration can be suppressed. That is, as compared with the case where the above-described technique is not used, it is unnecessary to consider the degradation in the design stage of the logical block 2, so that the degree of design difficulty can be reduced. The lower limit of the voltages at which the logical block 2 can normally operate differs depending on variations in semiconductor processes, accumulated operating times, and operating environments of the semiconductor processes. That is, there are various factors of variation. However, the semiconductor device 1 itself searches for the lower limit voltage value at which the logical block 2 normally operates, and performs the main setting of the voltage value for operating the logical block 2. Therefore, it is possible to set appropriate voltages for the semiconductor device 1 regardless of the above-described variation factors.

### First Embodiment

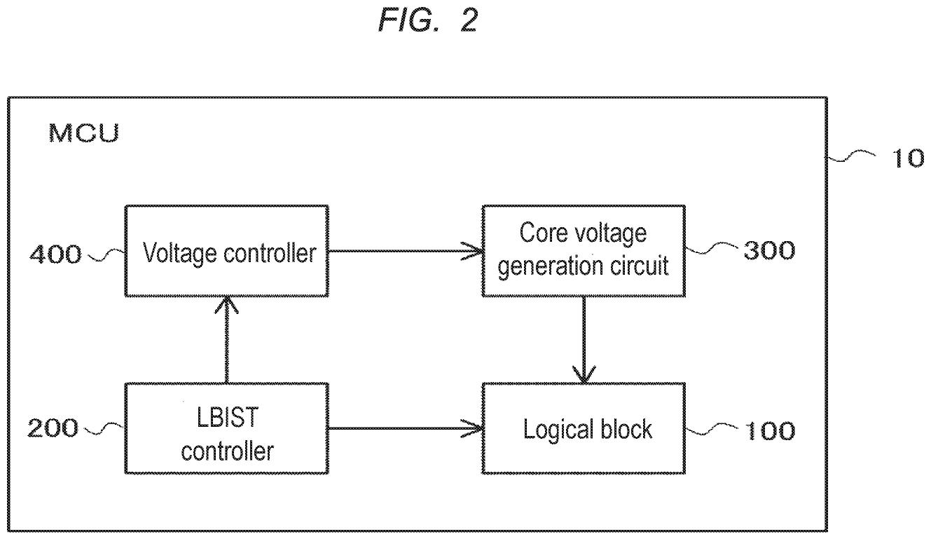

Next, a detailed explanation of the first embodiment is described. FIG. 2 is a block diagram showing an exemplary configuration of the micro controller unit (MCU) 10 according to the first embodiment. The MCU 10 is an exemplary semiconductor device 1 of FIG. 1. As shown in FIG. 2, the MCU 10 includes a logical block 100, a LBIST controller 200, a core voltage generation circuit 300, and a voltage controller 400.

The logical block 100 corresponds to the logical block 2 of FIG. 1, and is a block of circuits for performing logical operations. For example, the logical block 100 is arithmetic circuits such as Central Processing Unit cores.

The LBIST controller 200 is a circuit for controlling a logic BIST (LBIST for the logical block 100. The LBIST controller 200 corresponds to the diagnosis section 3 of FIG. 1, and performs LBIST tests on the logical block 100 to diagnose the operation of the logical block 100. The LBIST controller 200 diagnoses by this testing whether the logical block 100 exhibits a predetermined Performance, more particularly a predetermined performance to be met by the MCU 10 as normal products.

Specifically, the LBIST controller 200 diagnoses whether or not the logical block 100 is operable at an operation frequency of a predetermined frequency (hereinafter, referred to as a target frequency).

The core voltage generation circuit 300 generates a voltage for operating the logical block 100, i.e., a voltage core voltage, and applies the voltage to the logical block 100. The core voltage generation circuit 300 is, for example, a DC-DC converter that converts a predetermined power supply voltage into a voltage specified by the voltage controller 400. Note that the core voltage generation circuit 300 is not limited to a specific configuration as long as it is a circuit that applies voltages specified by the voltage controller 400 to the logical block 100. For example, the core voltage generation circuit 300 may be a switching regulator or an low drop out regulator. The core voltage generation circuit 300 is not necessarily included in the MCU 10, and may be, for example, an external power supply IC (Integrated Circuit).

The Voltage controller 400 corresponds to the voltage controller 4 in FIG. 1, and sets the core voltage voltages. The voltage controller 400 sets a lower limit voltage value, which is diagnosed by the LBIST controller 200 as being capable of operation the logical block 100 at a predetermined performance, as a voltage value of core voltage. The voltage controller 400 sets core voltage from a predetermined lower limit value that can be set as core voltage to a predetermined upper limit value that can be set as Core voltage. In the present embodiment, the Voltage controller 400 sequentially performs the temporary setting of core voltage so as to raise the voltage value by a predetermined step from the predetermined lower limit value, and searches for the lowest voltage value which is diagnosed by the LBIST controller 200 as being capable of operation the logical block 100 at a predetermined performance. Then, the voltage controller 400 determines the lowest voltage capable of operation the logical block 100 at a predetermined performance as the voltage core voltage. In the present embodiment, as described above, the voltage controller 400 performs the provisional setting of core voltage so as to gradually increase the voltage value from the predetermined lower limit value, but may perform the search by sequentially performing the provisional setting of core voltage so as to decrease the voltage value from the predetermined upper limit value by a predetermined step.

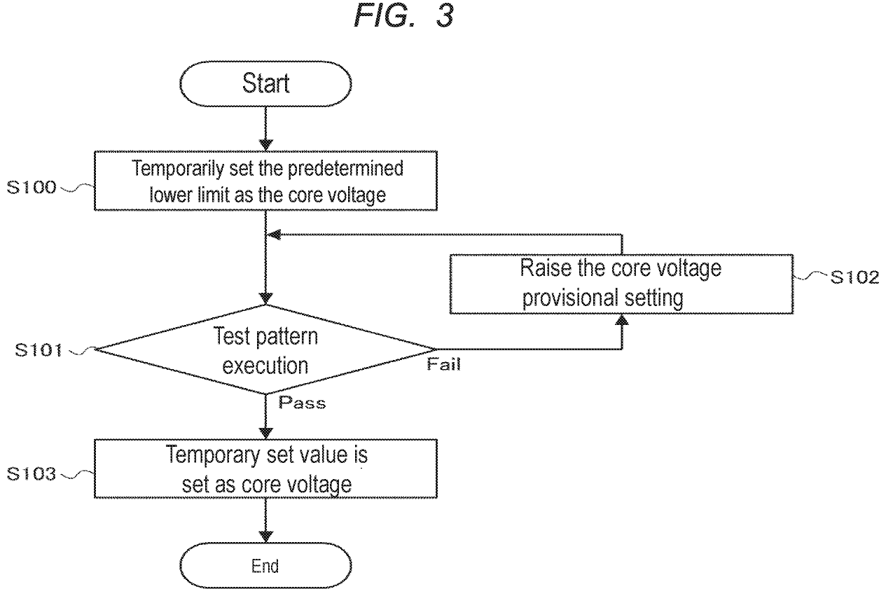

FIG. 3 is a flow chart showing an exemplary Core voltage setting operation in the MCU 10. Hereinafter, referring to FIG. 3, the setting operation of the core voltage will be described. The setting operation of the core voltage shown in FIG. 3 is performed, for example, at the time of starting the MCU 10 or at regular intervals.

In S100, the voltage controller 400 sets a predetermined lower limit as core voltage. Specifically, the voltage controller 400 controls the core voltage generation circuit 300 to generate a predetermined lower limit core voltage. Note that the voltage value set at this time is a temporary set value because it is a set value for searching for the lowest voltage value diagnosed by the LBIST controller 200 as being capable of operation the logical block 100 at a predetermined performance (specifically, for example, a target frequency). After step S100, the process proceeds to step S101.

In step S101, the LBIST controller 200 inputs a test pattern to the logical block 100, and diagnoses whether or not the logical block 100 exhibits a predetermined performance by comparing the outputs of the logical block 100 corresponding to the input with expected values. If the predetermined performance is not exerted (Fail in step S101), the process proceeds to step S102, and if the predetermined performance is exerted (Pass in step S101), the process proceeds to step S103.

In step S102, the voltage controller 400 sets a voltage value higher than the voltage value of the currently set core voltage by a predetermined step as core voltage. That is, the voltage controller 400 raises the provisional set value of core voltage to the present value. Thus, the core voltage generation circuit 300 applies a voltage higher than the present voltage by a predetermined step size to the logical block 100. After step S102, the process returns to step S101 and the above diagnoses are repeated.

If the diagnostics in step S101 pass, then in step S103, the voltage controller 400 determines the present tentative setting as the core voltage setting. That is, the voltage controller 400 sets the lower limit voltage value for passing the diagnostics as the voltage value for operating the logical block 100.

The first embodiment has been described above. In the MCU 10 according to the first embodiment, the voltage controller 400 sets core voltage based on the result of the LBIST. Therefore, while the logical block 100 is operated at a predetermined performance, the core voltage can be suppressed to the minimum required operating voltages. Therefore, since the core voltage can be set to the minimum required operating voltages, degradation of the Logical block 100 can be suppressed. In the design of the logical block 100, a design considering the degree of degradation of the logical block 100 is required. However, in the present embodiment, as described above, the degradation of the logical block 100 can be suppressed, so that the degree of difficulty in designing the logical block 100 can be reduced as compared with the case where the configuration according to the present embodiment is not provided. In addition, since the MCU 10 itself has a configuration for executing the above-described core voltage setting operation, it is possible to set appropriate voltages according to individual differences in semiconductor processes such as variations in semiconductor processes, accumulated operating times, operating environments, and the like.

### Second Embodiment

Next, the second embodiment will be described. It is known that in a miniaturized semiconductor process (e.g., a 28 nm process or a process miniaturized to more than 28 nm process), when the temperature is lowered, the performance (specifically, the operating frequency) of the semiconductor process is lowered. Therefore, when the logical block 100 is operated in a lower temperature environment using the core voltage set based on the diagnostic result in a certain temperature environment, the logical block 100 may not exhibit a predetermined performance. Therefore, in the present embodiment, the voltages to be set are adjusted in accordance with the temperature environments at the time of setting the core voltage.

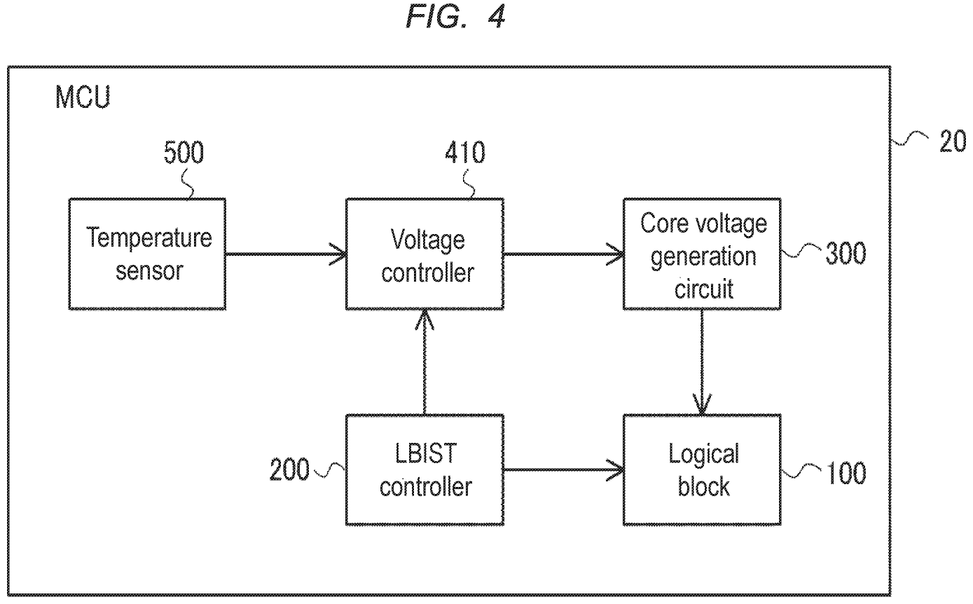

FIG. 4 is a block diagram showing an exemplary configuration of the MCU 20 according to the second embodiment. The MCU 20 is different from the MCU 10 according to the first embodiment in that the temperature sensor 500 is added and the voltage controller 400 is replaced with the voltage controller 410. Hereinafter, description overlapping with the first embodiment is omitted, and points different from the first embodiment will be described.

The temperature sensor 500 is a sensor circuit for measuring the Junction temperature (Temperature inside the MCU 20) of the MCU 20. For example, the temperature sensor 500 includes a resistor whose resistance varies depending on temperature. As such a resistive element, for example, a bipolar transistor element or a diode element is used. The temperature sensor 500 outputs voltages depending on temperature by changing the resistance values of the resistive elements according to temperature.

When finally determining the voltage value of core voltage, the voltage controller 410 sets, as the voltage value of core voltage, a voltage value obtained by adding a predetermined value corresponding to the temperature measured by the temperature sensor 500 to the lower limit voltage value that passes the diagnostic.

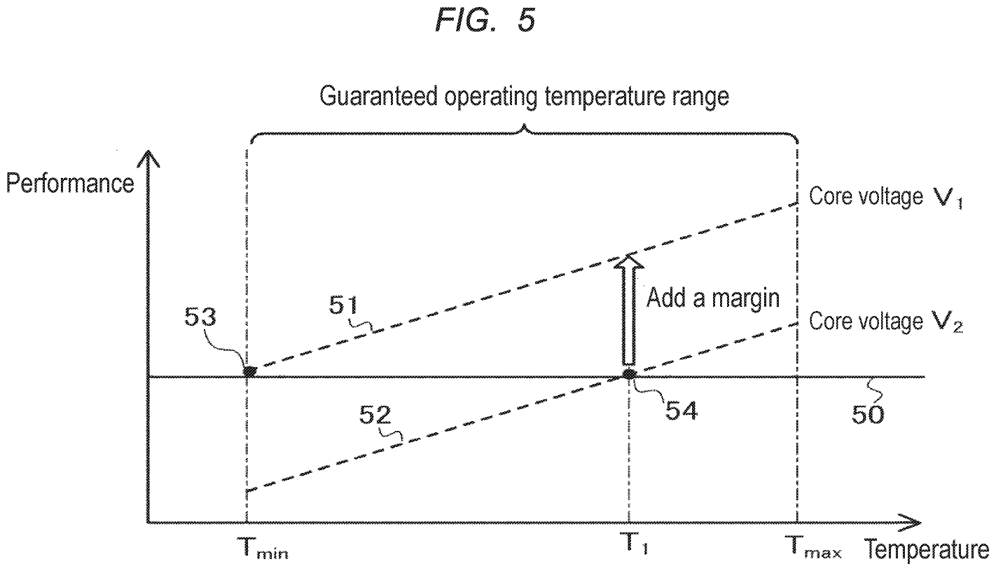

FIG. 5 is a graphical representation schematically illustrating the temperature characteristics of the logical block 100. As discussed above, the performance of the logical block 100 is temperature dependent. Specifically, as the temperature is lowered, the performance is also lowered. In FIG. 5, a solid line 50 indicates a predetermined performance, e.g., a target frequency. The broken line 51 indicates the temperature characteristic when the voltage V1 is set as Core voltage, and the broken line 52 indicates the Temperature characteristic when the voltage V2 is set as Core voltage. These voltages have a relation of V1>V2. The operation assurance temperature of the logical block 100 is a temperature ranging from the Tₘᵢₙ to the Tₘₐₓ in FIG. 5. That is, the Logical block 100 is required to exhibit a predetermined Performance in the Temperature range from the Tₘᵢₙ to the Tₘₐₓ.

Here, it is assumed that temperature when core voltage is set is Tₘᵢₙ. At this time, it is assumed that the V1 is set as the lowest core voltage satisfying the predetermined performance. That is, it is assumed that the setting indicated by the point 53 in FIG. 5 is performed. In this instance, the temperature when the core voltage is set is the lower limit of the operation-guaranteed temperature range. Therefore, the performance of the logical block 100 is unlikely to fall below the present performance within the operation guaranteed temperature.

On the other hand, it is assumed that Temperature when Core voltage is set is T1 (where Tₘᵢₙ<T₁≤Tₘₐₓ). At this time, it is assumed that the V2 is set as the lowest core voltage satisfying the predetermined performance. That is, it is assumed that the setting indicated by the point 54 in FIG. 5 has been performed. If temperature falls below the T1, then the performance of logical block 100 may fall below the present performance. That is, if temperature drops below the T1, the logical block 100 will not satisfy the predetermined performance. Therefore, in the present embodiment, the voltage controller 410 does not set the voltage value set as core voltage as V2, but sets a value obtained by adding a margin corresponding to the T1 to the V2 as core voltage. That is, when temperature fluctuates, the voltage controller 410 adds a margin corresponding to the temperature at the time of setting core voltage so that performance does not change on the broken line 52 but performance changes on the broken line 51. The margin is predetermined for each temperature, and the voltage controller 410 determines the voltage value by referring to the margin for each temperature stored in advance. The margin, i.e., the predetermined value to be added, is specified in advance, for example, experimentally. For example, as margins (predetermined values), a larger value is used as the temperature at the time of setting core voltage (i.e., at the time of diagnosing) is higher. As a result, a predetermined performance can be maintained in a logical block manufactured by a semiconductor process in which the performance of the semiconductor process is lowered when the temperature of the semiconductor process is lowered.

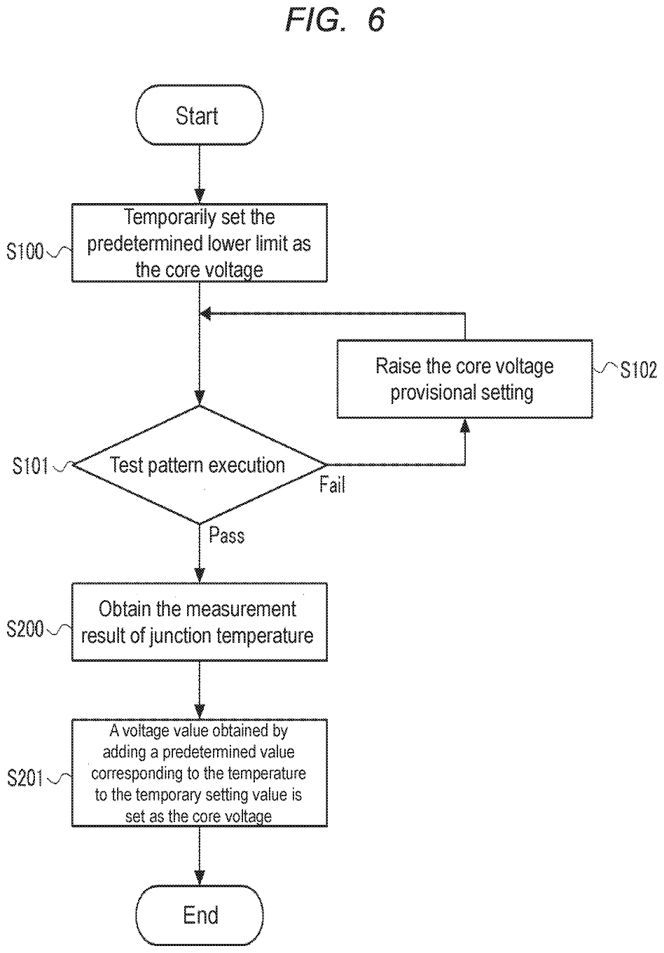

FIG. 6 is a flow chart showing an exemplary core voltage setting operation in the MCU 20. Hereinafter, referring to FIG. 6, the setting operation of core voltage in the MCU 20 will be described. The setting operation of the core voltage shown in FIG. 6 is performed, for example, at the time of starting the MCU 20 or at regular intervals. As shown in FIG. 6, the setting operation of core voltage in the MCU 20 is different from the setting operation in the MCU 10 shown in FIG. 3 in that the step S103 is replaced with the step S200 and the step S201. Hereinafter, an operation different from that of FIG. 3 will be described.

In the present embodiment, when it is diagnosed in step S101 that the logical block 100 exhibits a predetermined performance (Pass in step S101), the process proceeds to step S200. That is, when the lower limit of the core voltage at which the logical block 100 exhibits the predetermined performance is specified by the processing in step S102 from step S100, the processing proceeds to step S200. Also in the present embodiment, the search may be performed by sequentially performing the provisional setting of the core voltage so as to drop the voltage value from the predetermined upper limit value by a predetermined step.

In step S200, the voltage controller 410 obtains the Junction temperature of the MCU 20 measured by the temperature sensor 500. After step S200, the process proceeds to step S201.

In step S201, the voltage controller 410 sets, as core voltage, a voltage value obtained by adding a predetermined value corresponding to the temperature acquired in step S200 to the lower limit voltage value specified by the process from step S100 to step S102. That is, the voltage controller 410 sets, as core voltage, a voltage value obtained by adding a predetermined value corresponding to temperature to the provisional set value passed diagnosing in the step S101. In other words, the voltage controller 410 actually sets, as core voltage, a voltage value obtained by adding a predetermined value corresponding to Junction temperature to the lower limit voltage value found by the operation of the step S102 from the step S100.

The second embodiment has been described above. In the present embodiment, as described above, the core voltage is set by adding margins corresponding to the temperature at the time of setting core voltage. Therefore, even if the temperature environments fluctuate after the core voltage is set, the logical block 100 can operate while maintaining a predetermined performance.

### Third Embodiment

Typically, the lowest core voltage for logical block 100 to exert a predetermined performance increases as degradation progresses. Therefore, the lowest core voltage can be used as an index indicating the degree of degradation.

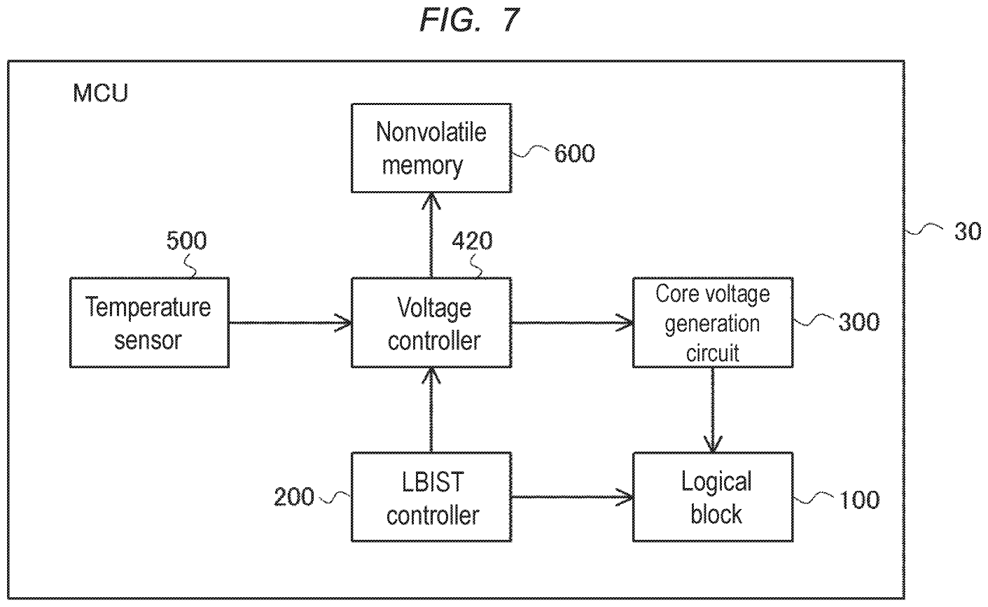

FIG. 7 is a block diagram showing an exemplary configuration of the MCU 30 according to the third embodiment. The MCU 30 is different from the MCU 20 according to the second embodiment in that a non-volatile memory 600 is added and the voltage controller 410 is replaced with the voltage controller 420. Hereinafter, description overlapping with the second embodiment is omitted, and points different from the second embodiment will be described. Note that the technology according to this embodiment is not limited to the structure according to the second embodiment, and can be combined with the structure according to the first embodiment.

The non-volatile memory 600 stores time-series data of voltage values set as core voltage. The non-volatile memory 600 stores the core voltage that is finally determined as the set value, rather than storing the tentative set value set sequentially for the search. That is, not the voltage value set in step S100, but the voltage value set in step S103 or step S201 is stored in the non-volatile memory 600.

As described above, the set core voltage rises as the degradation progresses. Therefore, the lifetime of the MCU 30 (logical block 100) can be estimated by analyzing the time-series data of the voltages set as core voltage. In this embodiment, since the time-series data of the voltage value set as core voltage is stored in the non-volatile memory 600, the data for lifetime analysis can be stored. The lifetime analysis process may be executed by the MCU 30 or by another device.

The voltage controller 420 differs from the voltage controller 410 in that it further has a function of outputting alarm signals. The voltage controller 420 outputs an alarm signal when setting a value exceeding a predetermined threshold value as the voltage value of the core voltage, that is, when setting a value exceeding the predetermined threshold value as the voltage value of the core voltage. For example, the threshold value is equal to or less than a predetermined upper limit value that can be set as core voltage, and a value in the vicinity of the upper limit value is used as the threshold value. When the set core voltage exceeds the threshold value, it means that the degradation has progressed to the degree of degradation corresponding to the threshold value. Therefore, by outputting an alarm signal, it is possible to notify that the deterioration reaches a predetermined reference.

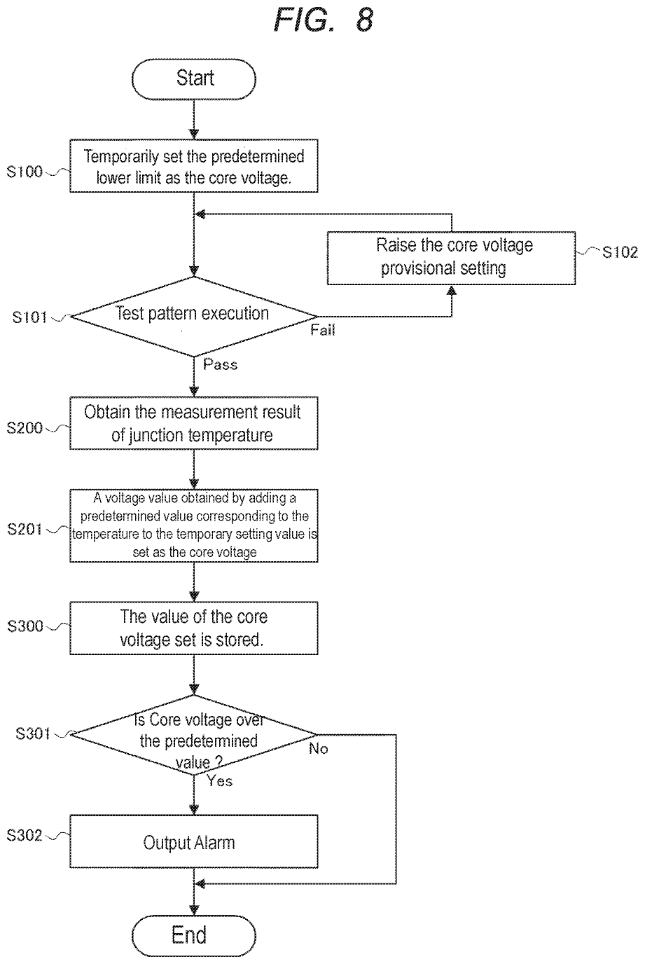

FIG. 8 is a flow chart showing an exemplary Core voltage setting operation in the MCU 30. Hereinafter, referring to FIG. 8, the setting operation of core voltage in the MCU 30 will be described. The setting operation of the core voltage shown in FIG. 8 is performed, for example, at the time of starting the MCU 30 or at regular intervals. As shown in FIG. 8, the setting operation of core voltage in the MCU 30 is different from the setting operation in the MCU 20 shown in FIG. 6 in that a step S302 is added from the step S300 after the step S201. Hereinafter, an operation different from that of FIG. 6 will be described. When core voltage is set in step S201, the process proceeds to step S300. In step S300, the voltage controller 420 stores the voltage value of the core voltage set in step S201 in the non-volatile memory 600. At this time, the voltage controller 420 may store the cumulative value of the MCU 30 operating time and the set value of the core voltage in association with each other in the non-volatile memory 600. In this manner, by storing the voltage value in association with the operating time, data more suitable for analysis can be accumulated. Although the voltage value set by the voltage controller 420 is stored in the non-volatile memory 600 in the present embodiment, a monitor circuit for monitoring the core voltage may be provided in the MCU 30, and the core voltage detected by the monitor circuit may be stored in the non-volatile memory 600. After step S300, the process proceeds to step S301.

In step S301, the voltage controller 420 determines whether or not the voltage value set in step S201 exceeds a predetermined voltage value. When the set voltage value exceeds the predetermined threshold value (YES in step S301), the process proceeds to step S302, and when the set voltage value does not exceed the predetermined threshold value (NO in step S301), the setting operation ends. In step S302, the voltage controller 420 outputs an alarm indicating that the degradation has reached a predetermined criterion, and then ends the setting operation.

The third embodiment has been described above. According to the present embodiment, data for analyzing the lifetime of the MCU 30 can be accumulated. It is also possible to inform that the deterioration has progressed until it reaches a predetermined criterion.

In the embodiment described above, the voltage controller 400, 410, and 420 have been described as hardware configurations, but these functions may be implemented by software. In this case, it is realized by causing a processor to execute a computer program.

Also, the programs described above may be stored and provided to a computer using various types of non-transitory computer readable media. Non-transitory computer readable media includes various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory, a CD-R, a CD-R/W, solid-state memories (e.g., masked ROM, PROM (Programmable ROM), EPROM (Erasable PROM, flash ROM, RAM (Random Access Memory)). The program may also be supplied to the computer by various types of transitory computer-readable media. Examples of transitory computer-readable media include electrical signals, optical signals, and electromagnetic waves. The transitory computer readable medium may provide the program to the computer via wired or wireless communication paths, such as electrical wires and optical fibers.

Although the invention made by the inventor has been specifically described based on the embodiment, the present invention is not limited to the embodiment already described, and it is needless to say that various modifications can be made without departing from the gist thereof.

What is claimed is:

1. A semiconductor device comprising:
a logical block;
a diagnosis section for diagnosing the operation of the logical block; and
a voltage controller for setting a voltage value for operating the Logical block using a lower limit voltage value diagnosed by the Diagnosis section when the Logical block operates normally.

2. The semiconductor device according to claim 1,
wherein said voltage controller sets said lower limit voltage value as a voltage value for operating said logical block.

3. The semiconductor device according to claim 1, further comprising:
a temperature sensor for measuring Junction temperature,
wherein the voltage controller sets a voltage value obtained by adding a predetermined value corresponding to a temperature measured by the temperature sensor to a lower limit voltage value diagnosed by the diagnosis section when the logical block operates normally, as a voltage value for operating the logical block.

4. The semiconductor device according to claim 3,
wherein the higher the diagnostic temperature measured by the temperature sensor, the greater the voltage voltages.

5. The semiconductor device according to claim 1,
wherein said voltage controller outputs alarm signals when a value exceeding predetermined thresholds is set as a voltage value for operating said logical block.

6. The semiconductor device according to claim 1, further comprising:
a storage unit for storing time-series data of the set voltages.

7. A voltage setting method comprising:
searching step for setting a temporary voltage value for operating logical block, and searching for a lower limit voltage value at which the logical block operates normally by diagnosing whether or not the logical block operates normally with the temporary voltage value; and
a setting step for setting of a voltage value for operating the logical block using the found lower limit voltage value.

8. The voltage setting method according to claim 7,
wherein the lower limit voltage value is set as a voltage value for operating the logical block.

9. The voltage setting method according to claim 7,
wherein a voltage value obtained by adding a predetermined value according to Junction temperature to the found voltage value of the lower limit is set as a voltage value for operating the logical block.

10. The voltage setting method according to claim 9,
wherein a higher voltage is added as the diagnostic temperature increases.

11. The voltage setting method according to claim 7,
wherein when a value exceeding a predetermined threshold value is set as a voltage value for operating the logical block, the voltage setting method outputs an alarm signal.

12. The voltage setting method according to claim 7,
wherein time-series data of the set voltage values is stored.
